(19) United States
(12) Patent Application Publication
(10) Pub. No.: US 2015/0009481 A1
(43) Pub. Date: Jan. 8, 2015

(54) Lithography Apparatus and System, a Method of Calibrating a Lithography Apparatus, and Device Manufacturing Methods

(71) Applicant: ASML Netherlands B.V, Veldhoven (NL)

(72) Inventor: Patricius Aloysius Jacobus Tinnemans, Hapert (NL)

(73) Assignee: ASML Netherlands B.V, Veldhoven (NL)

(21) Appl. No.: 14/377,152

(22) PCT Filed: Jan. 24, 2013
(86) PCT No.: PCT/EP2013/051308

§ 371 Date: Aug. 6, 2014

Related U.S. Application Data
(60) Provisional application No. 61/651,417, filed on May 24, 2012.
(60) Provisional application No. 61/597,562, filed on Feb. 10, 2012.

(51) Int. Cl. G03F 7/20

(52) U.S. Cl. CPC G03F 7/70558
USPC 355/67

(57) ABSTRACT

There is disclosed a lithography or exposure apparatus and system, a method of calibrating a lithography or exposure apparatus, and a device manufacturing method. In an embodiment, there is provided an exposure system including a first exposure apparatus and a second exposure apparatus, wherein a data processing device of each of the first and second apparatuses is configured to calculate a control signal using a response function; the combined performance of the programmable patterning device and projection system of each of the first and second apparatuses differs, at least due to manufacturing error; and the response function used by the first apparatus is identical to the response function used by the second apparatus.

### CROSS-REFERENCE TO RELATED APPLICATIONS

This application claims the benefit of U.S. provisional application 61/597,562, which was filed on Feb. 10, 2012 and U.S. provisional application 61/651,417, which was filed on May 24, 2012 and which are incorporated herein in its entirety by reference.

### FIELD

The present invention relates to a method of calibrating a lithography or exposure apparatus against a reference lithography or exposure apparatus, a lithography or exposure system comprising the calibrated lithography or exposure apparatus and the reference lithography or exposure apparatus, a device manufacturing method using the calibrated lithography or exposure apparatus, a lithography or exposure apparatus configured to perform calculations using a response function that is shift and/or rotation invariant and a device manufacturing method using the lithography or exposure apparatus.

### BACKGROUND

A lithographic or exposure apparatus is a machine that applies a desired pattern onto a substrate or part of a substrate. The apparatus may be used, for example, in the manufacture of integrated circuits (ICs), flat panel displays and other devices or structures having fine features. In a conventional lithographic or exposure apparatus, a patterning device, which may be referred to as a mask or a reticle, may be used to generate a circuit pattern corresponding to an individual layer of the IC, flat panel display, or other device). This pattern may transferred on (part of) the substrate (e.g. silicon wafer or a glass plate), e.g. via imaging onto a layer of radiation-sensitive material (resist) provided on the substrate.

Instead of a circuit pattern, the patterning device may be used to generate other patterns, for example a color filter pattern, or a matrix of dots. Instead of a conventional mask, the patterning device may comprise a patterning array that comprises an array of individually controllable elements that generate the circuit or other applicable pattern. An advantage of such a “maskless” system compared to a conventional mask-based system is that the pattern can be provided and/or changed more quickly and for less cost.

Thus, a maskless system includes a programmable patterning device (e.g., a spatial light modulator, a contrast device, etc.). The programmable patterning device is programmed (e.g., electronically or optically) to form the desired patterned beam using the array of individually controllable elements. Types of programmable patterning devices include micro-mirror arrays, liquid crystal display (LCD) arrays, grating light valve arrays, arrays of self-emissive contrast devices, a shutter element/matrix and the like. A programmable patterning device could also be formed from an electro-optical deflector, configured for example to move spots of radiation projected onto a target (e.g., a substrate) or to intermittently direct a radiation beam away from the target (e.g., a substrate), for example to a radiation beam absorber. In either such arrangement, the radiation beam may be continuous.

### SUMMARY

A desired device pattern to be formed on a substrate may be defined using a vector design package, such as GDSII. The output file from such a design package may be referred to as a vector-based representation of the desired device pattern. In a maskless system, the vector-based representation will be processed to provide a control signal to drive a programmable patterning device. The control signal may comprise a sequence of setpoints (e.g. voltages or currents) to be applied to, e.g., a plurality of self-emissive contrast devices or a micro-mirror array.

For a given desired device pattern, the calculations to provide the control signal may vary from one lithography or exposure apparatus to another. This is because in general the calculations should take account of the detailed properties of all components that participate in forming the radiation dose pattern on the target (e.g., substrate). These components may include the programmable patterning device and/or a projection system for example. The characteristics of the components will tend to vary from one machine to another, even in nominally identical machines, for example due to manufacturing variation.

Customers may need to perform simulations. Such simulations may be used to verify that the performance of their lithography or exposure apparatus is suitable for achieving a desired device performance, for example. Alternatively or additionally, the simulations may be used to design a suitable target device pattern for achieving desired device performance. The simulations may be used to calculate suitable optical proximity correction (OPC) features to include in the target device pattern for example.

It is undesirable, for example, to have to provide large amounts of information to customers to enable them to perform simulations. It is undesirable, for example, to have to provide such information individually for each machine in a group, even where the group has nominally identical machines.

The differences between apparatuses mentioned above may cause differences in the performance of the apparatuses. The differences in performance may cause variation in the dose pattern formed on the target (e.g., substrate) even when the input desired device pattern is identical. The variations in dose pattern may occur even between nominally identical machines. Such variation may complicate the task of designing a suitable target device pattern for use in a plurality of different lithography or exposure apparatuses and/or lead to undesirable differences in the performance/characteristics of nominally identical devices produced by different lithography or exposure apparatuses.

It is desirable, for example, to address at least one of the problems mentioned above. For example, it is desirable to provide a method of calibrating a lithography or exposure apparatus so that relevant information about its performance can be passed more easily to a customer. For example, it is desirable to provide a method of calibrating a lithography or exposure apparatus so that variation in performance in a group of different lithography or exposure apparatuses is reduced.

According to an embodiment, there is provided an exposure system comprising a first exposure apparatus and a second exposure apparatus, wherein: the first and second apparatuses each comprise: a programmable patterning device configured to produce a plurality of radiation beams to apply individually controllable doses to a target, a projection system configured to project each of the radiation beams onto a respective location on the target, and a data processing device configured to provide a control signal for the programmable patterning device, the control signal representing the set of target dose values to be applied by the plurality of radiation beams to form a desired dose pattern on the target, wherein: the data processing device of the first apparatus is configured to calculate the control signal using a response function that describes the relationship between a set of target dose values and a desired or requested resulting dose pattern on the target for the first apparatus, the data processing device of the second apparatus is configured to calculate the control signal using a response function that describes the relationship between a set of target dose values and a desired or requested resulting dose pattern on the target for the second apparatus, the combined performance of the programmable patterning device and projection system of the first apparatus differs from the combined performance of the programmable patterning device and projection system of the second apparatus, at least due to manufacturing error, and the response function used by the first apparatus matches the response function used by the second apparatus.

According to an embodiment, there is provided a method for calibrating a target exposure apparatus against a reference exposure apparatus or a calculated reference exposure apparatus, wherein: the target apparatus and reference or calculated reference apparatus each comprise: a programmable patterning device to produce a plurality of radiation beams to apply individually controllable doses to a target, a projection system to project each of the radiation beams onto a respective location on the target, and a data processing device to provide a control signal for the programmable patterning device, the control signal representing the set of target dose values to be applied by the plurality of radiation beams to form a desired dose pattern on the target; the data processing device of the target apparatus calculates the control signal using a response function that describes the relationship between a set of target dose values and a desired or requested resulting dose pattern on the target for the target apparatus; the data processing device of the reference apparatus or of the calculated reference apparatus calculates the control signal using a response function that describes the relationship between a set of target dose values and a desired or requested resulting dose pattern on the target for the reference apparatus or calculated reference apparatus, the method comprising adapting the response function of the target apparatus to match the response function of the reference apparatus or of the calculated reference apparatus.

According to an embodiment, there is provided a device manufacturing method using a target exposure apparatus that has been calibrated against a reference exposure apparatus or a calculated reference exposure apparatus, wherein the target apparatus and the reference or calculated reference apparatus each comprise: a programmable patterning device to produce a plurality of radiation beams to apply individually controllable doses to a target, a projection system to project each of the radiation beams onto a respective location on the target, and a data processing device to provide a control signal for the programmable patterning device, the control signal representing the set of target dose values to be applied by the plurality of radiation beams to form a desired dose pattern on the target; the data processing device of the target apparatus calculates the control signal using a response function that describes the relationship between a set of target dose values and a desired or requested resulting dose pattern on the target for the target apparatus; the data processing device of the reference apparatus or of the calculated reference apparatus calculates the control signal using a response function that describes the relationship between a set of target dose values and a desired or requested resulting dose pattern on the target for the reference apparatus or calculated reference apparatus; and the combined performance of the programmable patterning device and projection system of the target apparatus differs from the combined performance of the programmable patterning device and projection system of the reference or calculated reference apparatus, at least due to manufacturing error, the method comprising: using the data processing device of the target apparatus to calculate a control signal using the response function, wherein the response function used by the target apparatus matches the response function used by the reference or calculated reference apparatus; applying the control signal to the programmable patterning device of the target apparatus in order to produce a plurality of radiation beams; and projecting the plurality of radiation beams onto a target.

According to an embodiment, there is provided an exposure apparatus comprising a programmable patterning device configured to produce a plurality of radiation beams to apply individually controllable doses to a target; a projection system configured to project each of the radiation beams onto a respective location on the target; and a data processing device configured to provide a control signal for the programmable patterning device, the control signal representing the set of target dose values to be applied by the plurality of radiation beams to form a desired dose pattern on the target, wherein the data processing device calculates the control signal using a response function that describes the relationship between a set of target dose values and a desired or requested resulting dose pattern on the target, and the response function is shift and/or rotation invariant.

According to an embodiment, there is provided a device manufacturing method, comprising: using a plurality of radiation beams to apply individually controllable doses to a target; projecting each of the radiation beams onto a respective location on the target; and providing a control signal for the programmable patterning device, the control signal representing the set of target dose values to be applied by the plurality of radiation beams to form a desired dose pattern on the target, wherein the control signal is calculated using a response function that describes the relationship between a set of target dose values and a desired or requested resulting dose pattern on the target; and the response function is shift and/or rotation invariant.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a part of a lithographic or exposure apparatus according to an embodiment of the invention;

FIG. 2 depicts a top view of a part of the apparatus of FIG. 1 according to an embodiment of the invention;

FIG. 3 depicts a highly schematic, perspective view of a part of a lithographic or exposure apparatus according to an embodiment of the invention;

FIG. 4 depicts a schematic top view of projections by the apparatus according to FIG. 3 onto a substrate according to an embodiment of the invention;

FIG. 5 depicts in cross-section, a part of an embodiment of the invention;

FIG. 6 depicts a portion of a data-path to convert a vector-based representation of a desired device pattern to a control signal;

FIG. 7 depicts a portion of a spot exposure grid;

FIG. 8 depicts a portion of a rasterization grid;

FIG. 9 depicts a target lithography or exposure apparatus and a reference lithography or exposure apparatus, and matching of a stored response function in the target apparatus to a stored response function in the reference apparatus;

FIG. 10 depicts a variation with position on a portion of a target (e.g., substrate) of a value of a performance metric; and

FIG. 11 depicts the portion shown in FIG. 10 with a uniform performance metric corresponding to a uniform response function.

### DETAILED DESCRIPTION

An embodiment of the present invention relates to an apparatus that may include a programmable patterning device that may, for example, be comprised of an array or arrays of self-emissive contrast devices. Further information regarding such an apparatus may be found in PCT patent application publication no. WO 2010/032224 A2, U.S. patent application publication no. US 2011-0188016, U.S. patent application No. 61/473,636 and U.S. patent application No. 61/524,190 which are hereby incorporated by reference in their entireties. An embodiment of the present invention, however, may be used with any form of programmable patterning device including, for example, those discussed above.

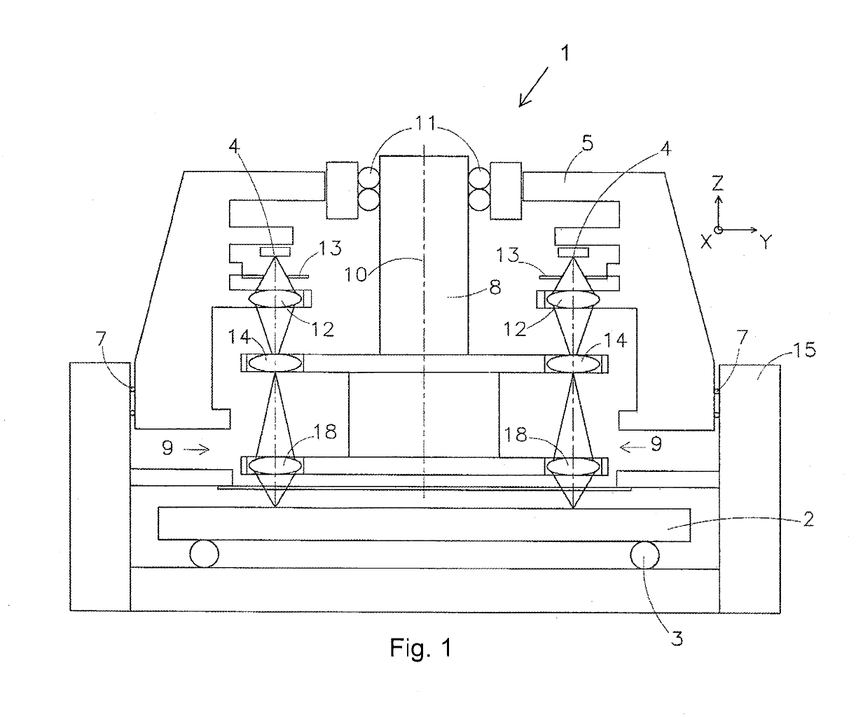

FIG. 1 schematically depicts a schematic cross-sectional side view of a part of a lithographic or exposure apparatus. In this embodiment, the apparatus has individually controllable elements substantially stationary in the X-Y plane as discussed further below although it need not be the case. The apparatus 1 comprises a substrate table 2 to hold a substrate, and a positioning device 3 to move the substrate table 2 in up to 6 degrees of freedom. The substrate may be a resist-coated substrate. In an embodiment, the substrate is a wafer. In an embodiment, the substrate is a polygonal (e.g. rectangular) substrate. In an embodiment, the substrate is a glass plate. In an embodiment, the substrate is a plastic substrate. In an embodiment, the substrate is a foil. In an embodiment, the apparatus is suitable for roll-to-roll manufacturing.

The apparatus 1 further comprises a plurality of individually controllable self-emissive contrast devices 4 configured to emit a plurality of beams. In an embodiment, the self-emissive contrast device 4 is a radiation emitting diode, such as a light emitting diode (LED), an organic LED (OLED), a polymer LED (PLED), or a laser diode (e.g., a solid state laser diode). In an embodiment, each of the individually controllable elements 4 is a blue-violet laser diode (e.g., Sanyo model no. DL-3146-151). Such diodes may be supplied by companies such as Sanyo, Nichia, Osram, and Nitride. In an embodiment, the diode emits UV radiation, e.g., having a wavelength of about 365 nm or about 405 nm. In an embodiment, the diode can provide an output power selected from the range of 0.5-200 mW. In an embodiment, the size of laser diode (naked die) is selected from the range of 100-800 micrometers. In an embodiment, the laser diode has an emission area selected from the range of 0.5-5 micrometers². In an embodiment, the laser diode has a divergence angle selected from the range of 5-44 degrees. In an embodiment, the diodes have a configuration (e.g., emission area, divergence angle, output power, etc.) to provide a total brightness more than or equal to about 6.4×10⁸ W/(m².sr).

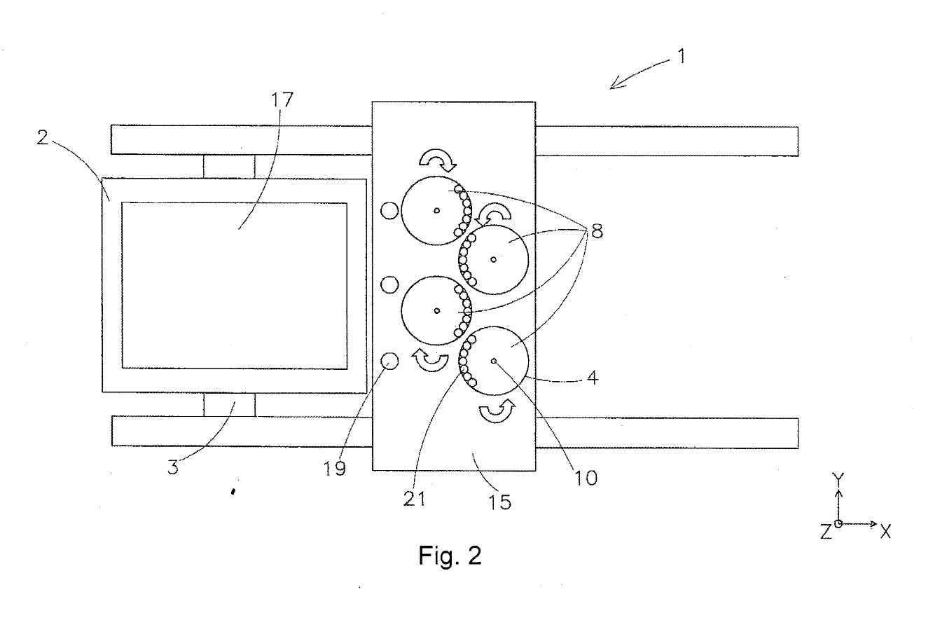

The self-emissive contrast devices 4 are arranged on a frame 5 and may extend along the Y-direction and/or the X direction. While one frame 5 is shown, the apparatus may have a plurality of frames 5 as shown in FIG. 2. Further arranged on the frame 5 is lens 12. Frame 5 and thus self-emissive contrast device 4 and lens 12 are substantially stationary in the X-Y plane. Frame 5, self-emissive contrast device 4 and lens 12 may be moved in the Z-direction by actuator 7. Alternatively or additionally, lens 12 may be moved in the Z-direction by an actuator related to this particular lens. Optionally, each lens 12 may be provided with an actuator.

The self-emissive contrast device 4 may be configured to emit a beam and the projection system 12, 14 and 18 may be configured to project the beam onto a target portion of the substrate. The self-emissive contrast device 4 and the projection system form an optical column. The apparatus 1 may comprise an actuator (e.g. motor) 11 to move the optical column or a part thereof with respect to the substrate. Frame 8 with arranged thereon field lens 14 and imaging lens 18 may be rotatable with the actuator. A combination of field lens 14 and imaging lens 18 forms movable optics 9. In use, the frame 8 rotates about its own axis 10, for example, in the directions shown by the arrows in FIG. 2. The frame 8 is rotated about the axis 10 using an actuator (e.g. motor) 11. Further, the frame 8 may be moved in a Z direction by motor 7 so that the movable optics 9 may be displaced relative to the substrate table 2.

An aperture structure 13 having an aperture therein may be located above lens 12 between the lens 12 and the self-emissive contrast device 4. The aperture structure 13 can limit diffraction effects of the lens 12, the associated self-emissive contrast device 4, and/or of an adjacent lens 12/self-emissive contrast device 4.

The depicted apparatus may be used by rotating the frame 8 and simultaneously moving the substrate on the substrate table 2 underneath the optical column. The self-emissive contrast device 4 can emit a beam through the lenses 12, 14, and 18 when the lenses are substantially aligned with each other. By moving the lenses 14 and 18, the image of the beam on the substrate is scanned over a portion of the substrate. By simultaneously moving the substrate on the substrate table 2 underneath the optical column, the portion of the substrate which is subjected to an image of the self-emissive contrast device 4 is also moving. By switching the self-emissive contrast device 4 “on” and “off” (e.g., having no output or output below a threshold when it is “off” and having an output above a threshold when it is “on”) at high speed under control of a controller, controlling the rotation of the optical column or part thereof, controlling the intensity of the self-emissive contrast device 4, and controlling the speed of the substrate, a desired pattern can be imaged in the resist layer on the substrate.

FIG. 2 depicts a schematic top view of the apparatus of FIG. 1 having self-emissive contrast devices 4. Like the apparatus 1 shown in FIG. 1, the apparatus 1 comprises a substrate table 2 to hold a substrate 17, a positioning device 3 to move the substrate table 2 in up to 6 degrees of freedom, an alignment/level sensor 19 to determine alignment between the self-emissive contrast device 4 and the substrate 17, and to determine whether the substrate 17 is at level with respect to the projection of the self-emissive contrast device 4. As depicted the substrate 17 has a rectangular shape, however also or alternatively round substrates may be processed.

The self-emissive contrast device 4 is arranged on a frame 15. The self-emissive contrast device 4 may be a radiation emitting diode, e.g., a laser diode, for instance a blue-violet laser diode. As shown in FIG. 2, the self-emissive contrast devices 4 may be arranged into an array 21 extending in the X-Y plane.

The array 21 may be an elongate line. In an embodiment, the array 21 may be a single dimensional array of self-emissive contrast devices 4. In an embodiment, the array 21 may be a two dimensional array of self-emissive contrast device 4.

A rotating frame 8 may be provided which may be rotating in a direction depicted by the arrow. The rotating frame may be provided with lenses 14, 18 (show in FIG. 1) to provide an image of each of the self-emissive contrast devices 4. The apparatus may be provided with an actuator to rotate the optical column comprising the frame 8 and the lenses 14, 18 with respect to the substrate.

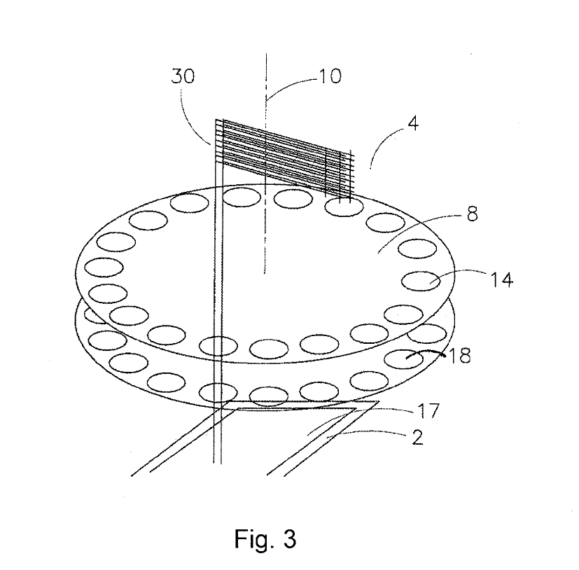

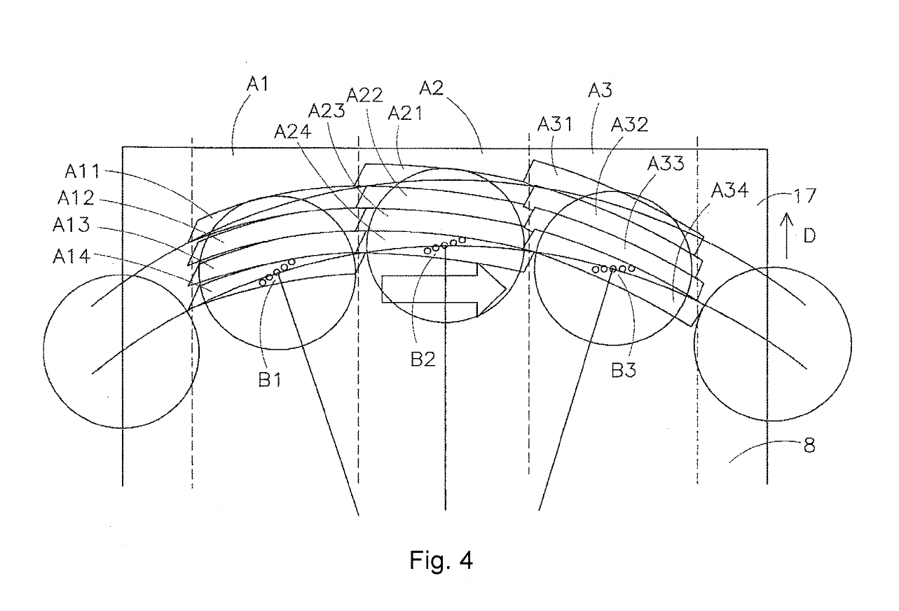

FIG. 3 depicts a highly schematic, perspective view of the rotating frame 8 provided with lenses 14, 18 at its perimeter. A plurality of beams, in this example 10 beams, are incident onto one of the lenses and projected onto a target portion of the substrate 17 held by the substrate table 2. In an embodiment, the plurality of beams are arranged in a straight line. The rotatable frame is rotatable about axis 10 by means of an actuator (not shown). As a result of the rotation of the rotatable frame 8, the beams will be incident on successive lenses 14, 18 (field lens 14 and imaging lens 18) and will, incident on each successive lens, be deflected thereby so as to travel along a part of the surface of the substrate 17, as will be explained in more detail with reference to FIG. 4. In an embodiment, each beam is generated by a respective source, i.e. a self-emissive contrast device, e.g. a laser diode (not shown in FIG. 3). In the arrangement depicted in FIG. 3, the beams are deflected and brought together by a segmented mirror 30 in order to reduce a distance between the beams, to thereby enable a larger number of beams to be projected through the same lens and to achieve resolution requirements to be discussed below.

As the rotatable frame rotates, the beams are incident on successive lenses and, each time a lens is irradiated by the beams, the places where the beam is incident on a surface of the lens, moves. Since the beams are projected on the substrate differently (with e.g. a different deflection) depending on the place of incidence of the beams on the lens, the beams (when reaching the substrate) will make a scanning movement with each passage of a following lens. This principle is further explained with reference to FIG. 4. FIG. 4 depicts a highly schematic top view of a part of the rotatable frame 8. A first set of beams is denoted by B1, a second set of beams is denoted by B2 and a third set of beams is denoted by B3. Each set of beams is projected through a respective lens set 14, 18 of the rotatable frame 8. As the rotatable frame 8 rotates, the beams B1 are projected onto the substrate 17 in a scanning movement, thereby scanning area A14. Similarly, beams B2 scan area A24 and beams B3 scan area A34. At the same time of the rotation of the rotatable frame 8 by a corresponding actuator, the substrate 17 and substrate table are moved in the direction D, which may be along the X axis as depicted in FIG. 2), thereby being substantially perpendicular to the scanning direction of the beams in the area's A14, A24, A34. As a result of the movement in direction D by a second actuator (e.g. a movement of the substrate table by a corresponding substrate table motor), successive scans of the beams when being projected by successive lenses of the rotatable frame 8, are projected so as to substantially abut each other, resulting in substantially abutting areas A11, A12, A13, A14 (areas A11, A12, A13 being previously scanned and A14 being currently scanned as shown in FIG. 4) for each successive scan of beams B1, areas A21, A22, A23 and A24 (areas A21, A22, A23 being previously scanned and A24 being currently scanned as shown in FIG. 4) for beams B2 and areas A31, A32, A33 and A34 (areas A31, A32, A33 being previously scanned and A34 being currently scanned as shown in FIG. 4) for beams B3. Thereby, the areas A1, A2 and A3 of the substrate surface may be covered with a movement of the substrate in the direction D while rotating the rotatable frame 8. The projecting of multiple beams through a same lens allows processing of a whole substrate in a shorter timeframe (at a same rotating speed of the rotatable frame 8), since for each passing of a lens, a plurality of beams scan the substrate with each lens, thereby allowing increased displacement in the direction D for successive scans. Viewed differently, for a given processing time, the rotating speed of the rotatable frame may be reduced when multiple beams are projected onto the substrate via a same lens, thereby possibly reducing effects such as deformation of the rotatable frame, wear, vibrations, turbulence, etc. due to high rotating speed. In an embodiment, the plurality of beams are arranged at an angle to the tangent of the rotation of the lenses 14, 18 as shown in FIG. 4. In an embodiment, the plurality of beams are arranged such that each beam overlaps or abuts a scanning path of an adjacent beam.

A further effect of the aspect that multiple beams are projected at a time by the same lens, may be found in relaxation of tolerances. Due to tolerances of the lenses (positioning, optical projection, etc), positions of successive areas A11, A12, A13, A14 (and/or of areas A21, A22, A23 and A24 and/or of areas A31, A32, A33 and A34) may show some degree of positioning inaccuracy in respect of each other. Therefore, some degree of overlap between successive areas A11, A12, A13, A14 may be required. In case of for example 10% of one beam as overlap, a processing speed would thereby be reduced by a same factor of 10% in case of a single beam at a time through a same lens. In a situation where there are 5 or more beams projected through a same lens at a time, the same overlap of 10% (similarly referring to one beam example above) would be provided for every 5 or more projected lines, hence reducing a total overlap by a factor of approximately 5 or more to 2% or less, thereby having a significantly lower effect on overall processing speed. Similarly, projecting at least 10 beams may reduce a total overlap by approximately a factor of 10. Thus, effects of tolerances on processing time of a substrate may be reduced by the feature that multiple beams are projected at a time by the same lens. In addition or alternatively, more overlap (hence a larger tolerance band) may be allowed, as the effects thereof on processing are low given that multiple beams are projected at a time by the same lens.

Alternatively or in addition to projecting multiple beams via a same lens at a time, interlacing techniques could be used, which however may require a comparably more stringent matching between the lenses. Thus, the at least two beams projected onto the substrate at a time via the same one of the lenses have a mutual spacing, and the apparatus may be arranged to operate the second actuator so as to move the substrate with respect to the optical column to have a following projection of the beam to be projected in the spacing.

In order to reduce a distance between successive beams in a group in the direction D (thereby e.g. achieving a higher resolution in the direction D), the beams may be arranged diagonally in respect of each other, in respect of the direction D. The spacing may be further reduced by providing a segmented mirror 30 in the optical path, each segment to reflect a respective one of the beams, the segments being arranged so as to reduce a spacing between the beams as reflected by the mirrors in respect of a spacing between the beams as incident on the mirrors. Such effect may also be achieved by a plurality of optical fibers, each of the beams being incident on a respective one of the fibers, the fibers being arranged so as to reduce along an optical path a spacing between the beams downstream of the optical fibers in respect of a spacing between the beams upstream of the optical fibers.

Further, such effect may be achieved using an integrated optical waveguide circuit having a plurality of inputs, each for receiving a respective one of the beams. The integrated optical waveguide circuit is arranged so as to reduce along an optical path a spacing between the beams downstream of the integrated optical waveguide circuit in respect of a spacing between the beams upstream of the integrated optical waveguide circuit.

A system may be provided for controlling the focus of an image projected onto a substrate. The arrangement may be provided to adjust the focus of the image projected by part or all of an optical column in an arrangement as discussed above.

In an embodiment the projection system projects the at least one radiation beam onto a substrate formed from a layer of material above the substrate 17 on which a device is to be formed so as to cause local deposition of droplets of the material (e.g. metal) by a laser induced material transfer.

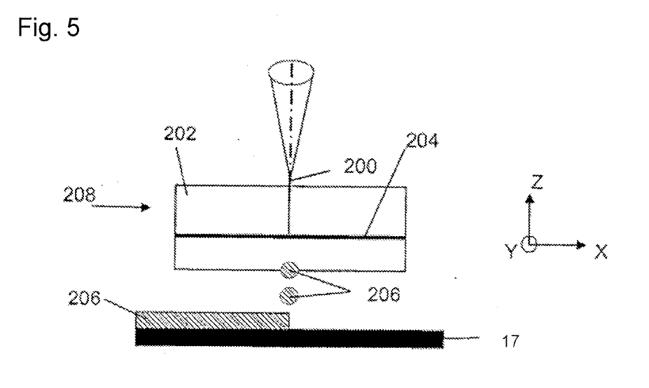

Referring to FIG. 5, the physical mechanism of laser induced material transfer is depicted. In an embodiment, a radiation beam 200 is focused through a substantially transparent material 202 (e.g., glass) at an intensity below the plasma breakdown of the material 202. Surface heat absorption occurs on a substrate formed from a donor material layer 204 (e.g., a metal film) overlying the material 202. The heat absorption causes melting of the donor material 204. Further, the heating causes an induced pressure gradient in a forward direction leading to forward acceleration of a donor material droplet 206 from the donor material layer 204 and thus from the donor structure (e.g., plate) 208. Thus, the donor material droplet 206 is released from the donor material layer 204 and is moved (with or without the aid of gravity) toward and onto the substrate 17 on which a device is to be formed. By pointing the beam 200 on the appropriate position on the donor plate 208, a donor material pattern can be deposited on the substrate 17. In an embodiment, the beam is focused on the donor material layer 204.

In an embodiment, one or more short pulses are used to cause the transfer of the donor material. In an embodiment, the pulses may be a few picoseconds or femto-seconds long to obtain quasi one dimensional forward heat and mass transfer of molten material. Such short pulses facilitate little to no lateral heat flow in the material layer 204 and thus little or no thermal load on the donor structure 208. The short pulses enable rapid melting and forward acceleration of the material (e.g., vaporized material, such as metal, would lose its forward directionality leading to a splattering deposition). The short pulses enable heating of the material to just above the heating temperature but below the vaporization temperature. For example, for aluminum, a temperature of about 900 to 1000 degrees Celsius is desirable.

In an embodiment, through the use of a laser pulse, an amount of material (e.g., metal) is transferred from the donor structure 208 to the substrate 17 in the form of 100-1000 nm droplets. In an embodiment, the donor material comprises or consists essentially of a metal. In an embodiment, the metal is aluminum. In an embodiment, the material layer 204 is in the form a film. In an embodiment, the film is attached to another body or layer. As discussed above, the body or layer may be a glass.

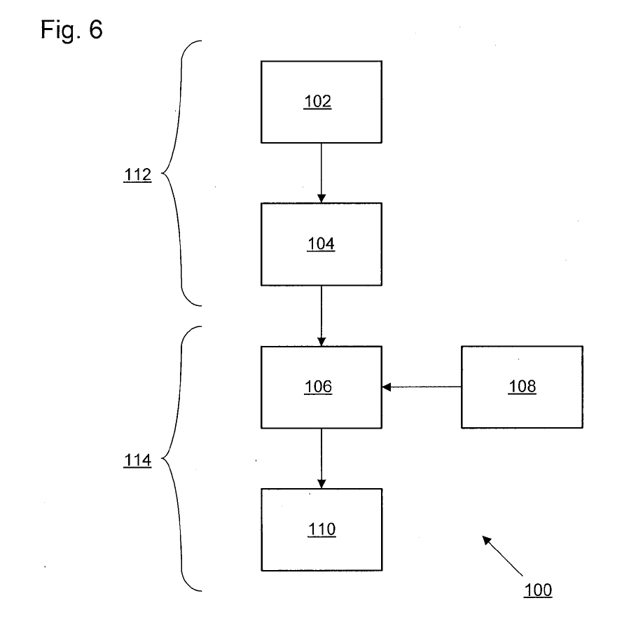

Hardware constituting a data processing system 100, which may also be referred to as a “data-path”, may be provided to convert a vector-based representation of a desired device pattern to be formed on a substrate to a control signal suitable to drive a programmable patterning device in such a way that a dose pattern of radiation that is suitable to form the desired device pattern is applied to a target (e.g., the substrate). FIG. 6 is a schematic illustration showing example processing stages that are included in such a data-path according to an embodiment. In an embodiment, each of the stages is connected directly to its neighboring stages. However, this need not be the case. In an embodiment, one or more additional processing stages are provided in between any of the stages shown. Additionally or alternatively, each of one or more of the stages comprises multiple stages. In an embodiment, the stages are implemented using a single physical processing unit (e.g. a computer or hardware that can carry out computing operations) or different processing units.

In the example shown in FIG. 6 a vector-based representation of a desired device pattern is provided in storage stage 102. In an embodiment, the vector-based representation is constructed using a vector design package, such as GDSII for example. The vector-based representation is forwarded to a rasterization stage 104, either directly or via one or more intermediate stages, from the storage stage 102.

Examples of an intermediate stage include a vector pre-processing stage and/or a low-pass filter stage. In an embodiment, the low-pass filter stage performs anti-aliasing processing.

The rasterization stage 104 converts the vector-based representation (or a processed version of the vector-based representation) of the desired device pattern to a rasterized representation of a desired dose pattern that corresponds to the desired device pattern (i.e. is suitable to form the desired device pattern by post-exposure processing of the substrate). In an embodiment, the rasterized representation comprises bitmap data. The bitmap data may be referred to as “pixelmap” data. In an embodiment, the bitmap data comprises a set of values indicating the desired dose (i.e. the dose per unit area) at each point on a grid of points. The grid of points may be referred to as a rasterization grid.

In an embodiment, the rasterized representation (as output from the rasterization stage 104 directly or after further processing) is supplied to a control signal generation stage 106. The control signal generation stage 106 is implemented as a single stage (as shown) or as a plurality of separate stages.

In an embodiment, the control signal generation stage 106 performs a mapping operation between the rasterization grid and the grid (which may be referred to as the “spot exposure grid”) defining the “positions” at which the patterning device can form spot exposures at target level. Each spot exposure comprises a dose distribution. The dose distribution specifies how the energy per unit area applied by the spot to the target (i.e. dose per unit area) varies as a function of position within the spot. In an embodiment, the position of the spot exposure is defined by reference to a characteristic point in the dose distribution. In an embodiment, the characteristic point is the position of maximum dose per unit area. In an embodiment, the position of maximum dose per unit area is in a central region of the spot. In an embodiment, the position of maximum dose per unit area is not in a central region of the spot. In an embodiment, the dose distribution is circularly symmetric. In such an embodiment, the spot may be referred to as a circular spot. In such an embodiment, the position of maximum dose per unit area may be located at the center of the circle. In an embodiment, the dose distribution is not circular. In an embodiment, the characteristic point in the dose distribution is the “center of mass” of the dose distribution (defined by direct analogy with the center of mass of a flat object having variable density, in which the dose per unit area of the spot exposure is the equivalent of the mass per unit area of the flat object). The “center of mass” of the dose distribution therefore represents the average location of the dose. In an embodiment, each grid point in the spot exposure grid represents the position of a different one of the spot exposures (e.g. the position of the characteristic point) that the patterning device (and/or projection system) can apply to the target.

In an embodiment, the lithography or exposure apparatus is configured to produce spot exposures of discrete “spots” (e.g. circular spots). In an example of such an embodiment, the intensity of a given radiation beam at the level of the target reaches zero at times in between the exposure of different spots by that radiation beam. In an embodiment, the lithography or exposure apparatus is configured to produce spot exposures in continuous lines. The continuous lines may be considered as a sequence of spot exposures in which the intensity of a given radiation beam at the level of the target does not reach zero in between exposure of different spots in the sequence by that radiation beam. An example embodiment of this type is described above with reference to FIG. 4. In an embodiment, each spot exposure corresponds to a region of radiation dose on the target that originates from a single self-emissive contrast device during a single period of that contrast device being driven at a constant power, for example. In an embodiment, each spot exposure corresponds to a region of radiation dose on the target that originates from a single mirror or group of mirrors in a micro-mirror array. In an embodiment, the mapping operation comprises interpolation between the rasterization grid and the spot exposure grid. In an embodiment, the mapping operation is configured to receive metrology data from a metrology data storage stage 108. In an embodiment, the metrology data specifies the position and/or orientation of the target (e.g., the mounted substrate), and/or of a previously formed device pattern on a mounted substrate, relative to the patterning device. In an embodiment, the metrology data also specifies measured distortions of a target (e.g., mounted substrate) or a previously formed device pattern. In an embodiment, the distortions include one or more of the following: shift, rotation, skew and/or magnification. The metrology data therefore provides information about how the interpolation/mapping between the rasterization grid and the spot exposure grid should be carried out in order to help ensure proper positioning of the desired dose pattern on the target.

In an embodiment, the control signal generation stage 106 is configured to calculate a set of target dose values representing the total dose (or energy) to be applied by each of the spot exposures. In an embodiment, the target dose values are converted to setpoint values to drive the programmable patterning device.

In an embodiment, the programmable patterning device is configured to produce a plurality of radiation beams having individually controllable intensities, for example by a plurality of self-emissive contrast devices each having an output intensity that depends on the size of an input signal. In an example of such an embodiment, the control signal generation stage 106 calculates a set of target intensity values representing the intensities that are suitable to achieve the set of target dose values. In the case where the total dose of a spot exposure depends only on the intensity of the radiation beam forming the spot exposure, the terms “target dose value” and “target intensity value” can be used interchangeably. In an embodiment, each spot exposure is produced by applying a driving signal (e.g. a voltage or current) to a radiation source, such as a self-emissive contrast device, for a certain (e.g., predetermined) time. In an embodiment, the setpoint value defines the signal level to apply. In an embodiment, the signal level determines the power output of a radiation source, such as a self-emissive contrast device. In an embodiment in which the patterning device comprises a micro-mirror array, the setpoint values define actuation states of the mirrors in the micro-mirror array. In an embodiment in which the micro-mirror array is a grayscale digital micro-mirror device (DMD), the setpoint values define the grayscale levels to be applied by the mirrors. In an embodiment, the grayscale levels are defined by controlling a process of high-speed switching of individual mirrors between at least two different tilt positions. In an embodiment in which the micro-mirror array comprises mirrors that are each selectively actuatable to one of a plurality of different tilt angles, the setpoint values define the tilt angles to be applied to the mirrors.

In an embodiment, the programmable patterning device is configured to produce a plurality of radiation beams having individually controllable exposure times. Each exposure time corresponds to the period of time for which the radiation corresponding to a given spot exposure is applied. In an example of such an embodiment, the control signal generation stage 106 calculates a set of target exposure times that are suitable to achieve the target dose values. In the case where the total dose of a spot exposure depends only on the exposure time, the terms “target dose value” and “target exposure time value” can be used interchangeably. In an embodiment, the exposure times are controlled using a shutter element or matrix of shutter elements positioned between a radiation source or sources (e.g. self-emissive contrast elements) and the target. In an example of such an embodiment, the radiation source or sources may be configured to remain “on” between exposures of different spots. The exposure times are determined by the length of time for which the relevant part of the shutter element or matrix of shutter elements is “open”. Alternatively or additionally, the exposure times are controlled by controlling a driving duration of the radiation source or sources (e.g. self-emissive contrast elements).

In an embodiment, the programmable patterning device is configured to produce a plurality of radiation beams having individually controllable intensities and individually controllable exposures times. In an example of such an embodiment, the control signal generation stage 106 calculates combinations of target intensity values and target exposure times that are suitable to achieve the target dose values.

In an embodiment, the calculation of the set of target dose values (intensity and/or exposure time values) accounts for one or more properties of the optical projection system and may therefore be referred to as an “inverse-optics” calculation. In an embodiment, the calculation accounts for the size and/or shape of individual spots. In an embodiment, the size and/or shape of individual spots are at least partially dictated by a property of the optical projection system. In an embodiment, the size and/or shape is defined for each of a given set of possible applied intensities or exposure times for the spot. The spot size and/or shape is defined, as described above, by the dose distribution or point spread function of the spot. In an embodiment, the calculation also takes into account deviation in the position of a spot from a nominal position defined by the ideal (i.e. engineering-error free and/or manufacturing-error free) spot exposure grid geometry.

In an embodiment the spots overlap with each other at target level (i.e. the dose distributions of spots extend so as to overlap with the dose distributions of other spots) so that the final dose per unit area achieved at a reference position in the spot exposure grid depends on the applied doses associated with a number of neighboring spots. This effect can be described (handled/modeled) mathematically by a convolution (or deconvolution) operation. In an embodiment the control signal generation stage 106 performs the reverse process to determine the spot exposure doses t be applied at each position for a given desired dose pattern (e.g. by determining the target intensity and/or exposure time values for each of the plurality of radiation beams that form the plurality of spot exposures). Therefore, in such an embodiment the control signal generation stage 106 performs a deconvolution (or convolution) operation. This operation is referred to below as a (de-)convolution operation to reflect the fact that it can be described equivalently as a convolution operation and as a deconvolution operation. In an embodiment the (de-)convolution operation is defined by a (de-) convolution kernel. In an embodiment the (de-)convolution kernel is represented by a (de-)convolution matrix. In an embodiment the coefficients of such a (de-)convolution matrix are interpreted as weights that define the extent to which the dose per unit area at points in the region of a reference point in the desired dose pattern should be taken into account when calculating the spot exposure dose value (e.g. intensity and/or exposure time values) for forming a spot exposure at the corresponding point in the spot exposure grid.

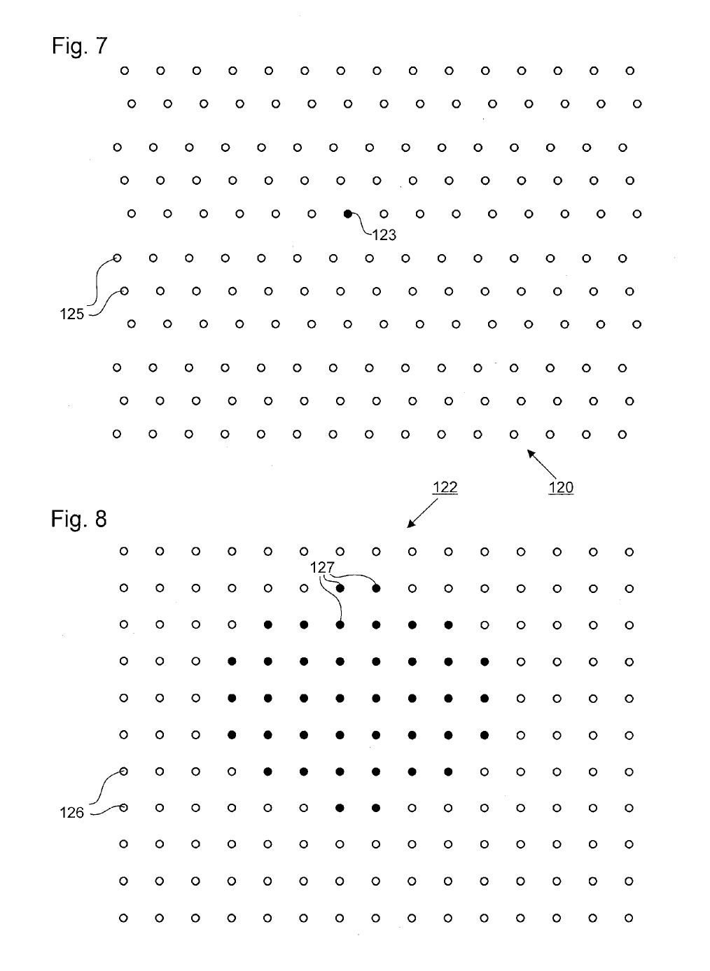

FIGS. 7 and 8 illustrate highly schematically a step in such a (de-)convolution operation.

FIG. 7 illustrates a portion of a highly schematic example spot exposure grid 120. Each point 125 in the grid 120 represents the nominal position of a spot on the target (e.g. the position of the characteristic point in the dose distribution of the spot) that will be formed by one of the plurality of beams controlled by the patterning device. The (de-)convolution operation aims to determine the spot exposure dose value (intensity and/or exposure time) of the radiation beam forming the spot exposure at each of the points 125. The spot exposure grid 120 will have a geometry that corresponds to the pattern of spot exposures that the patterning device is able to form on the target. In an embodiment, the geometry of the spot exposure grid is irregular. In an irregular grid, within the meaning of the present application, the density of grid points varies as a function of position so that it is not possible to construct the grid completely by tessellating a single unit cell that contains a single grid point only. FIG. 7 illustrates the geometry of an irregular grid in a highly schematic manner. The geometry of the grid 120 depicted does not necessarily resemble a spot exposure grid associated with a commercial device, which may be considerably more complex.

FIG. 8 illustrates an example portion of a rasterization grid 122. The solid grid points 127 represent schematically the grid points that could be involved with a (de-) convolution operation to determine the target dose value for the spot exposure at position 123 (chosen at random) in the grid of FIG. 7. Application of the (de-) convolution operation to derive the dose value for the spot exposure at solid grid point 123 will involve weighted contributions of the samples of the desired dose pattern (“dose values”) at a plurality of grid points in the rasterization grid in the region of the rasterization grid corresponding to the position of the reference grid point 123. In an embodiment, a (de-)convolution kernel expressed as a matrix will define which grid points 126 are involved (by the positions of the non-zero coefficients in the matrix) and the extent to which the grid points are involved (by the values of the non-zero coefficients in the matrix).

In an embodiment, the nature of the (de-)convolution operation is different for different points (or even in between different points) in the spot exposure grid. In an embodiment, such variation takes into account variations in the optical performance of the patterning device for example. In an embodiment the variations in optical performance are obtained using a calibration measurement. In an embodiment a library of (de-)convolution kernels, optionally obtained from calibration measurements, is stored and accessed as needed.

In an embodiment, the control signal generation stage 106 converts the sequence of target dose values for the radiation beams to setpoint values in order to generate the control signal. In an embodiment, the setpoint values take into account the nature of the patterning device. For example, where the patterning device comprises a plurality of self-emissive contrast devices, the setpoint values in such an embodiment account for non-linearity in the response of the self-emissive contrast devices (e.g. non-linearity in the variation of output power as a function of applied setpoint/voltage/current). In an embodiment the setpoint values take into account variation in a property of nominally identical contrast devices, by calibration measurement for example. In an embodiment in which the patterning device comprises a micro-mirror array, the setpoint values take into account the response of the mirrors (e.g. the relationship between the applied setpoint value(s) for a given mirror or group of mirrors and the intensity of the associated radiation beam(s)).

A control signal output stage 110 receives the control signal from the control signal generation stage and supplies the signal to the patterning device. The control signal generation stage 106 and control signal output stage 110 may be referred to as a “controller” to control a programmable patterning device of the lithography or exposure apparatus to emit beams that apply the target dose values necessary to produce a desired dose pattern on a target.

In the example shown in FIG. 6, stages 102 and 104 operate in an offline part 112 of the data-path and stages 106-110 operate in an online (i.e. real-time) part 114 of the data-path. However, this is not essential. In an embodiment all or a portion of the functionality associated with stage 104 is carried out online. Alternatively or additionally, all or a portion of the functionality of stages 106 and/or 108 are carried out offline.

As mentioned above, it may be desirable to simulate operation of the lithography or exposure apparatus. Such simulation may be useful for designing a target device pattern, for example for determining suitable optical proximity corrections (OPC). The simulation may be used to predict process performance. For example the simulation may be used to predict the effect on line width of dose variations. Predictions from the simulation can be used to verify that manufactured products will be within specification.

In general, the simulation will use information about all relevant components of the lithography or exposure apparatus. In the embodiments discussed above, for example, the information could include details about the dose distribution and position (e.g. the position of the characteristic point in the dose distribution) of each spot exposure that the programmable patterning device and projection system can form on the substrate, for all possible combinations of setpoint value applied to the programmable patterning device. In an embodiment, this information may be represented mathematically by a convolution operator or a “point spread function”.

The point spread function is an example of a “response function” describing mathematically the relationship, or a component in the relationship, between a set of target dose values and the resulting dose pattern on the target (e.g., substrate).

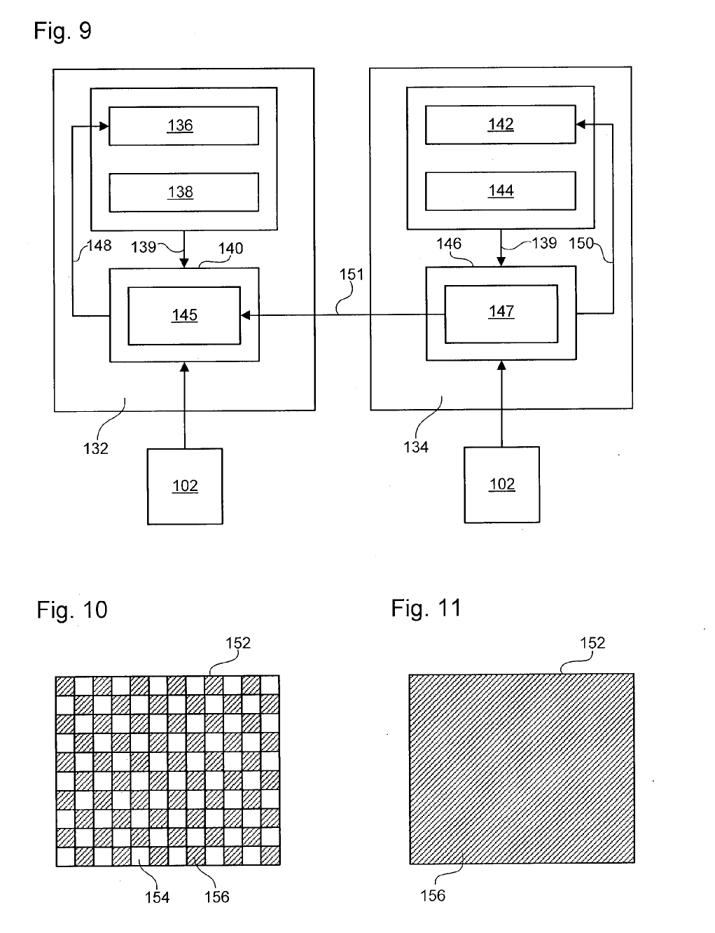

FIG. 9 depicts a target lithography or exposure apparatus 132 and a reference lithography or exposure apparatus 134. Example method of calibrating the target apparatus 132 against the reference apparatus 134 are described below.

In an embodiment, the target apparatus 132 comprises a programmable patterning device 136, a projection system 138 and a data processing device 140. In an embodiment, the reference apparatus 134 also comprises a programmable patterning device 142, a projection system 144, and a data processing device 146. In each case, the programmable patterning device 136,142 is configured to produce a plurality of radiation beams to apply individually controllable doses to a target (e.g. substrate). The nature of the doses to be applied is determined by a control signal 148,150 that the programmable patterning device 136,142 receives from the data processing device 140,146. In an embodiment the control signal comprises setpoint data. In an embodiment the setpoint data represents a set of target dose values to be applied by the plurality of radiation beams. In an embodiment each target dose value defines the dose distribution of a spot exposure formed by the radiation beam to which the target dose value is applied. The data processing device 140,146 calculates the control signal based on a desired device pattern or desired dose pattern input by a user from storage stage 102. The plurality of radiation beams from the programmable patterning device 136,142 are output to a projection system 138,144. The projection system 138,144 projects the radiation beams onto locations on the target (e.g. substrate).

The combined performance of programmable patterning device and projection system of each of the two apparatuses will be different, even if the two apparatuses are nominally the same (i.e. of the same type and configuration), due to inevitable manufacturing error. In an embodiment the effect of such error is determined and corrected for in the datapath. In an embodiment the effect of such error is determined using a calibration measurement.

In an embodiment, the data processing device 140,146 of each of the target apparatus and the reference apparatus is configured to calculate the control signal 148,150 using a response function stored in an internal memory 145,147. The response function describes the relationship between one or more sets of target dose values and one or more desired or requested resulting dose patterns on the target (e.g. substrate). The response function may be referred to as a transfer function. In an embodiment, the response function is an impulse response function. In an embodiment, the response function of the target apparatus is made to match the response function of the reference apparatus. In an embodiment, the response functions are substantially identical. In this way, the response of the two apparatuses to a given set of target dose values will be substantially identical. In an embodiment, the adaptation comprises reading 151 of the response function of the reference apparatus by the target apparatus. Alternatively or additionally, the response functions of the target and reference apparatuses may be independently defined to be the same, for example by reference to an external standard or the response function of another lithography or exposure apparatus.

In an embodiment the reference apparatus is a calculated reference lithography or exposure apparatus. In an embodiment, the calculated reference apparatus is a theoretical construct based on a plurality of lithography or exposure apparatuses. In an embodiment, the calculated reference apparatus represents a lithography or exposure apparatus having a performance that is an average of the performances of the plurality of lithography or exposure apparatuses. In an embodiment, the calculated reference apparatus represents a mean or median state of the plurality of lithography or exposure apparatuses. In an embodiment, the response function of the calculated reference apparatus is derived from the mean or median of the response functions of the plurality of lithography or exposure apparatuses.

Matching the response functions allows a device pattern that has been derived for use with the reference apparatus, for example a device pattern including OPCs, to be usable directly with the target apparatus. Maintaining uniformity in the quality and/or properties of devices manufactured using the two different apparatus is facilitated.

In an embodiment, the data processing devices are configured so that the response functions are representable by a shift invariant operator or a rotation invariant operator (e.g. radial operator). The response functions are thus “uniform”. Response functions that are shift invariant can be represented more easily (e.g. using fewer bits) than response functions that are not shift invariant because it is not necessary to define how the response function varies as a function of position at target level. Response functions that are rotation invariant can be represented more easily (e.g. using fewer bits) than response functions that are not rotation invariant because it is not necessary to define how the response function varies as a function of rotation position at target level. Arranging for the response functions to be shift and/or rotation invariant thus makes the response functions more compact. In an embodiment, the response functions also comprise less information about the detailed configuration of the lithography or exposure apparatus, such as the detailed configuration of the datapath, programmable patterning device or the projection system. In an embodiment, the response function does contain detailed information about the geometry of the spot exposure grid and/or the optics used to project the spot exposures onto the target. The response functions can thus be distributed to customers more easily and/or handled/interpreted by customers more easily. The response functions can be more easily matched for two or more lithography or exposure apparatuses.

In an embodiment, the data processing devices are configured so that the response functions are representable by a shift invariant operator or a rotation invariant operator even when the response of the programmable patterning device, projection system, or combination of the programmable patterning device and projection system is not shift invariant or rotation invariant.

For example, in arrangements of the type described above with reference to FIGS. 1-4 and 7, the distribution of spot exposures is irregular (the “spot exposure grid” is irregular). The response of the combination of the programmable patterning device and the projection system is not shift invariant and is not rotation invariant. The spot exposure density varies as a function of position. Such variation in the spot exposure density tends to cause variation in performance parameters as a function of position. For example, the maximum achievable resolution will tend to vary in correspondence with the variation in spot exposure density. Generally, regions where the spot exposures are denser will be capable of forming higher resolution patterns than regions where the spot exposures are less dense.

In an embodiment, the response function used by the data processing device 145,147 is derived using as input (139) a response of the physical components of the lithography or exposure apparatus (e.g. the combined response of the programmable patterning device 136,142 and the projection system 138,144). In an embodiment, the response function is derived so that a performance metric is uniform (e.g. shift and/or rotation invariant). In an embodiment, the performance metric comprises one or more of the following metrics: resolution, normalized intensity log slope (NILS), contrast, line edge roughness (LER), line width roughness (LWR), and/or line end shortening (LES).

This may be achieved even when the response of the physical components of the lithography or exposure apparatus is not uniform. In an embodiment, the response function is derived so that the performance metric is shift and rotation invariant based on a lowest maximum achievable value of the performance metric for the two or more lithography or exposure apparatuses in which the response function is to be used. This approach achieves the maximum performance (based on the particular performance metric being used) that is possible in the two or more lithography or exposure apparatuses consistent with a uniform response function.

FIGS. 10 and 11 provide a schematic illustration of such a process for a portion 152 of a target (e.g., substrate) onto which the dose pattern is to be formed. FIG. 10 illustrates a response of one of a group of two or more lithography or exposure apparatuses. The response varies as a function of position. The variation is such that the maximum achievable value of a performance metric (e.g. resolution, NILS, contrast, LER, LWR and/or LES) is non-uniform. Regions 154 represent regions where the maximum achievable value of the performance metric is relatively high (e.g. where the density of points in the spot exposure grid is relatively high). Regions 156 represent regions where the maximum achievable value of the performance metric is relatively low (e.g. where the density of points in the spot exposure grid is relatively low). In an embodiment, the derivation of the response function to be used by the data processing device 140,146 comprises removing the position and/or rotation dependence of the response. In the example shown, this is achieved by adapting the response function to be consistent with a value of the performance metric that is uniform (shift and/or rotation invariant). In an embodiment, the uniform value of the performance metric is equal to the value in the regions 154. This transformation may be seen as expanding the regions 154 to cover the whole of the portion of the target 152 (FIG. 11).

In an embodiment, the process of matching the response functions used by data processing devices in different lithography or exposure apparatuses is used in two or more lithography or exposure apparatuses that are nominally identical to each other within manufacturing tolerance. Alternatively or additionally the process is used in two or more lithography or exposure apparatuses that are of different types but which have the same or similar performance. Alternatively or additionally the process is used in two or more lithography or exposure apparatuses that are of different types and which have different performances.

In an embodiment, the data processing devices of the target and reference apparatuses are both configured to apply a (de-)convolution operation to a rasterized representation of the desired dose pattern. In an embodiment, the (de-)convolution operation for the target apparatus is adjusted (for example so as to be different from the (de-)convolution operation for the reference apparatus) to achieve the matching, or assist with the matching, of the response function of the target apparatus to the response function of the reference apparatus. In an embodiment in which the (de-) convolution operation is implemented using a matrix kernel, the coefficients of the kernel are adapted to achieve the matching or assist with the matching.

In an embodiment, the response function is linear (in intensity or amplitude/phase). This is appropriate, for example, where the formation of the final dose pattern on the target (e.g. substrate) is derived from the sum of the dose distributions applied by different ones of the plurality of radiation beams, e.g. the sum of the dose distributions from different spot exposures. This arises where the imaging from different radiation beams (different spot exposures) is completely or predominantly incoherent, so there is no or negligible interference between different beams. It is also possible to define a linear (complex amplitude, i.e. amplitude and phase) response function where the imaging from different radiation beams is fully coherent. A linear response function can be defined in terms of two spatial dimensions. The linear response function may therefore be referred to as two-dimensional response function. Linear response functions can generally be represented more easily than non-linear or higher-dimensional response functions.

In an embodiment, the imaging between different radiation beams (e.g. different spot exposures) is partially coherent. In this case, it is not appropriate to use a two-dimensional linear response function as it cannot represent the behavior of the system sufficiently accurately. In an embodiment, a four dimensional response function may be defined in complex amplitude (i.e. amplitude and phase). In an embodiment, the four dimensional response function is referred to as a transmission-cross-coefficient.

In an embodiment, the response function comprises a set of (de-)convolution kernels. The (de-)convolution kernels are used where there is overlap in the dose distributions from different spot exposures at target level. In an embodiment, the derivation of a response function in the target apparatus that is matched to the response function in the reference apparatus is performed by varying the kernels in the target apparatus and/or the reference apparatus.

In an embodiment, the derivation of a response function in the target apparatus that is matched to the response function in the reference apparatus is performed such that the matching is achieved to a greater degree for a set of one or more specific dose pattern types than for dose pattern types that are not within the set. In an example of such an embodiment, the matching process is weighted (for example during a fitting process) to take more account of dose pattern types that are in the set than dose pattern types that are not within the set. In an embodiment, the accuracy with which dose pattern types in the set can be formed is considered to a greater degree than the accuracy with which dose pattern types not in the set can be formed when assessing whether the response function of the target apparatus is sufficiently well matched to the response function of the reference apparatus. In an embodiment, the matching is performed only in respect of the set of specific dose pattern types. In an example of such an embodiment the degree to which the target apparatus is capable of producing dose pattern types that are not within the set is not taken into account in the matching process.

Thus, the response function matching process can prioritize the dose pattern types that are actually going to be used by the target apparatus rather than trying to match the response function for all possible dose patterns, including for example dose patterns such as white noise which will very rarely if ever be required. The matching process can thus be carried out more efficiently. Additionally or alternatively, the computing resources used for the response matching function may be lower than the computing resources that would be used for a response function that is matched with respect to all possible patterns.

In an embodiment, the set comprises one or more of: one or more identical patterns at different rotational orientations; one or more identical patterns at different positions; one or more groups of plural parallel lines; one or more patterns to form contact hole patterns, one or more lines each having one or more non-parallel portions, and/or one or more lines each having one or more angles in the lines. In an embodiment, the one or more lines each having one or more angles in the lines comprise “L”-shaped lines (e.g. with sections connected together at about 90 degrees to each other) or “S”-shaped lines (e.g. with at least three different sections connected together at angles that turn in opposite senses). In an embodiment, the one or more lines each having one or more angles in the lines are used as a calibration pattern. In an embodiment, the one or more groups of parallel lines comprises at least two groups in which the line thicknesses are different in each group, the spacing between the lines is different in each group, and/or the ratio between a line thickness and the line spacing is different in each group. In an embodiment, the different rotational orientations comprise one or more of the following rotations about an axis perpendicular to the target, relative to a reference direction within the plane of the target: 0 degrees, 22.5 degrees, 45 degrees, 67.5 degrees, 90 degrees, 112.5 degrees, 135 degrees, 157.5 degrees, 180 degrees, 202.5 degrees, 225 degrees, 247.5 degrees, 270 degrees, 292.5 degrees, 315 degrees, or 337.5 degrees.

In accordance with a device manufacturing method, a device, such as a display, integrated circuit or any other item may be manufactured from the substrate on which the pattern has been projected.

Although specific reference may be made in this text to the use of lithographic or exposure apparatus in the manufacture of ICs, it should be understood that the lithographic or exposure apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one of various types of optical components, including refractive, diffractive, reflective, magnetic, electromagnetic and electrostatic optical components or combinations thereof.

While specific embodiments of the invention have been described above, it will be appreciated that the invention may be practiced otherwise than as described. For example, the embodiments of the invention may take the form of a computer program containing one or more sequences of machine-readable instructions describing a method as disclosed above, or a data storage medium (e.g. semiconductor memory, magnetic or optical disk) having such a computer program stored therein. Further, the machine-readable instruction may be embodied in two or more computer programs. The two or more computer programs may be stored on one or more different memories and/or data storage media.

The descriptions above are intended to be illustrative, not limiting. Thus, it will be apparent to one skilled in the art that modifications may be made to the invention as described without departing from the scope of the claims set out below.

1. An exposure system comprising a first exposure apparatus and a second exposure apparatus, wherein the first and second apparatuses each comprise:
a programmable patterning device configured to produce a plurality of radiation beams to apply individually controllable doses to a target,
a projection system configured to project each of the radiation beams onto a respective location on the target, and
a data processing device configured to provide a control signal for the programmable patterning device, the control signal representing the set of target dose values to be applied by the plurality of radiation beams to form a desired dose pattern on the target, wherein:
the data processing device of the first apparatus is configured to calculate the control signal using a response function that describes the relationship between a set of target dose values and a desired or requested resulting dose pattern on the target for the first apparatus,
the data processing device of the second apparatus is configured to calculate the control signal using a response function that describes the relationship between a set of target dose values and a desired or requested resulting dose pattern on the target for the second apparatus,
the combined performance of the programmable patterning device and projection system of the first apparatus differs from the combined performance of the programmable patterning device and projection system of the second apparatus, at least due to manufacturing error, and
the response function used by the first apparatus matches the response function used by the second apparatus.

2. The system according to claim 1, wherein the response of the programmable patterning device of either or both of the first and second apparatuses is not shift invariant or not rotation invariant.

3. The system according to claim 1, wherein the response of the projection system of either or both of the first and second apparatuses is not shift invariant or not rotation invariant.

4. The system according to claim 2, wherein the response functions of the first and second apparatuses are representable by a shift invariant operator.

5. The system according to any of claim 2, wherein the response functions of the first and second apparatuses are representable by a rotation invariant operator.

6. The system according to claim 1, wherein the response functions of the first and second apparatuses are linear in intensity, complex amplitude, or both intensity and complex amplitude.

7. The system according to claim 1, wherein the maximum value of a performance metric obtainable from the programmable patterning device and projection system of the first and/or second apparatus varies as a function of position on the target.

8. The system according to claim 7, wherein the response functions used by the data processing devices of the first and second apparatuses provide a maximum value of the performance metric that does not vary as a function of position on the target.

9. The system according to claim 8, wherein the maximum value of the performance metric provided by each of the response functions is equal to the lowest maximum value of the performance metric obtainable from the programmable patterning device and projection system of the first or second apparatus.

10. The system according to claim 1, wherein the programmable patterning device of either or both of the first and second apparatuses is configured to produce a plurality of radiation beams having individually controllable intensities, the data processing device being configured to calculate target intensity values as the target dose values.

11. The system according to claim 1, wherein the programmable patterning device of either or both of the first and second apparatuses is configured to produce a plurality of radiation beams having individually controllable exposure times, the data processing device being configured to calculate target exposure time values as the target dose values.

12. The system according to claim 1, wherein the response function used by the first apparatus matches the response function used by the second apparatus only for a set of one or more specific dose pattern types or to a greater degree for the set of one or more specific dose pattern types than for dose pattern types that are not within the set.

13. The system according to claim 12, wherein the set comprises one or more of: one or more identical patterns at different rotational orientations; one or more identical patterns at different positions; one or more groups of plural parallel lines; one or more patterns to form a contact hole pattern, one or more lines each having one or more non-parallel portions, and/or one or more lines each having one or more angles in the lines.

14. The system according to claim 1, wherein:
the data processing devices of the first and second apparatuses are both configured to apply a (de-)convolution operation to a rasterized representation of the desired dose pattern; and
the (de-)convolution operation for the first apparatus is made to be different from the (de-)convolution operation for the second apparatus to achieve the matching, or assist with the matching, of the response function of the first apparatus to the response function of the second apparatus.

15. A method for calibrating a target exposure apparatus against a reference exposure apparatus or a calculated reference exposure apparatus, wherein the target apparatus and reference or calculated reference apparatus each comprise:
a programmable patterning device to produce a plurality of radiation beams to apply individually controllable doses to a target,
a projection system to project each of the radiation beams onto a respective location on the target, and
a data processing device to provide a control signal for the programmable patterning device, the control signal representing the set of target dose values to be applied by the plurality of radiation beams to form a desired dose pattern on the target;
wherein the data processing device of the target apparatus calculates the control signal using a response function that describes the relationship between a set of target dose values and a desired or requested resulting dose pattern on the target for the target apparatus;
wherein the data processing device of the reference apparatus or of the calculated reference apparatus calculates the control signal using a response function that describes the relationship between a set of target dose values and a desired or requested resulting dose pattern on the target for the reference apparatus or calculated reference apparatus,
adapting the response function of the target apparatus to match the response function of the reference apparatus or of the calculated reference apparatus.
